(19) United States
(12) Patent Application Publication
(10) Pub. No.: US 2025/0145385 A1
(43) Pub. Date: May 8, 2025

(54) INTER-FLOOR CONVEYANCE DEVICE

(71) Applicant: DAIFUKU CO., LTD., Osaka-shi (JP)

(72) Inventors: Takato MATSUO, Shiga (JP); Keita INADOME, Shiga (JP); Jyunichi SAKAMOTO, Shiga (JP); Ryoji MORISHITA, Shiga (JP)

(73) Assignee: DAIFUKU CO., LTD., Osaka-shi (JP)

(21) Appl. No.: 18/930,118

(22) Filed: Oct. 29, 2024

(30) Foreign Application Priority Data
Nov. 7, 2023 (JP) 2023-190308

(51) Int. Cl. B65G 47/57

(52) U.S. Cl. CPC B65G 47/57

(57) ABSTRACT

To dispose more delivery conveyance devices around a transfer device. An inter-floor conveyance device includes: a raising and lowering section including a transfer mechanism configured to move in a vertical direction across a plurality of floors while holding a container and configured to transfer the container; and an intermediate conveyor configure to convey the container between the transfer mechanism and each of delivery conveyors configured to deliver the container to and from a ceiling conveyance device configured to convey the container.

This Nonprovisional application claims priority under 35 U.S.C. § 119 on Patent Application No. 2023-190308 filed in Japan on Nov. 7, 2023, the entire contents of which are hereby incorporated by reference.

### TECHNICAL FIELD

The present invention relates to an inter-floor conveyance device configured to convey a conveyance target across floors and transfer the conveyance target to and from each of delivery conveyance devices on the floors.

### BACKGROUND ART

Inter-floor conveyance devices convey articles across floors and transfer the articles to and from delivery conveyance devices on the floors. The delivery conveyance devices deliver the articles to and from conveyance devices, such as ceiling conveyance devices configured to convey the articles on the floors. For example, Patent Literature 1 discloses that in a tubular divider body provided so as to penetrate through a floor on each level, a transfer device configured to be raised and lowered by a raising and lowering unit directly transfers an article to and from loading and unloading conveyance devices (delivery conveyance devices) installed on the floors.

### CITATION LIST

### Patent Literature

### [Patent Literature 1]

Japanese Patent Application Publication Tokukai No. 2021-178712

### SUMMARY OF INVENTION

### Technical Problem

In the inter-floor conveyance device described above, end parts of the delivery conveyance devices configured to directly transfer an article to and from the transfer device are disposed in the vicinity of the transfer device. Therefore, the number of the end parts disposed around the transfer device, that is, the number of the delivery conveyance devices is limited to a small number.

It is an object of an aspect of the present invention to provide an inter-floor conveyance device that allows more delivery conveyance devices to be disposed around a transfer device.

### Solution to Problem

In order to solve the foregoing problem, an inter-floor conveyance device in accordance with an aspect of the present invention includes: a raising and lowering section including a transfer mechanism configured to move in a vertical direction across a plurality of floors while holding a conveyance target and configured to transfer the conveyance target; and an intermediate conveyance section configured to deliver the conveyance target between the transfer mechanism and each of delivery conveyance devices configured to deliver the conveyance target to and from an intra-floor conveyance device configured to convey the conveyance target.

### Advantageous Effects of Invention

According to an aspect of the present invention, it is possible to dispose more delivery conveyance devices around a transfer device.

### BRIEF DESCRIPTION OF DRAWINGS

FIG. 1 is a front view illustrating a configuration of a conveyance system in accordance with an embodiment of the present invention.

FIG. 2 is a plan view illustrating an arrangement configuration of an inter-floor conveyance device, delivery conveyors, and intermediate conveyors in the conveyance system.

FIG. 3 is a front view illustrating a configuration of a ceiling conveyance device in the conveyance system.

FIG. 4 is a perspective view illustrating an arrangement configuration of a transfer mechanism, the delivery conveyors, and the intermediate conveyor in the conveyance system.

FIG. 5 is a side view illustrating a configuration of a raising and lowering section included in the inter-floor conveyance device.

FIG. 6 is a perspective view illustrating a configuration of the transfer mechanism.

FIG. 7 is a plan view illustrating a configuration of a storage shelf provided in the lowermost part of the inter-floor conveyance device.

### DESCRIPTION OF EMBODIMENTS

### Configuration of Inter-Floor Conveyance Device

The following description will discuss a conveyance system 100 in accordance with an embodiment of the present invention in detail.

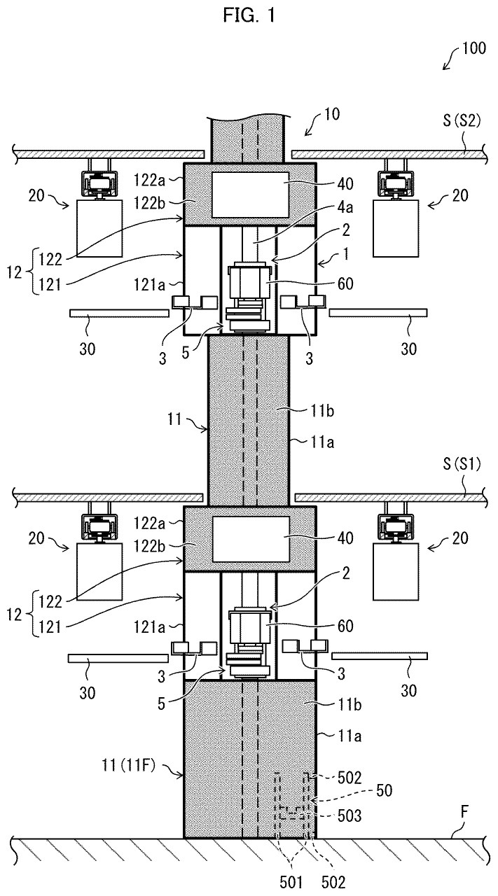

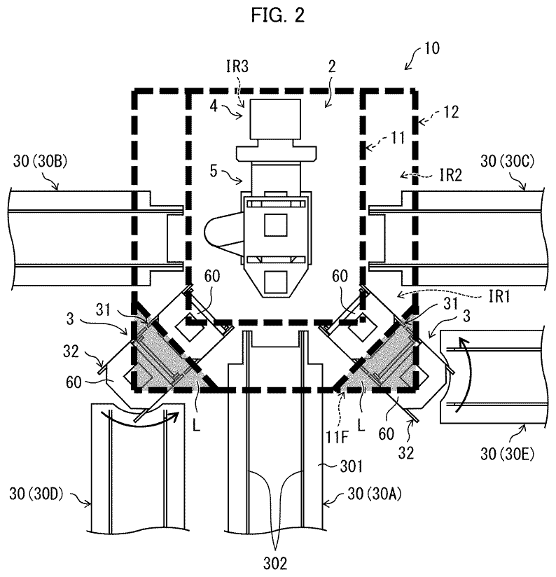

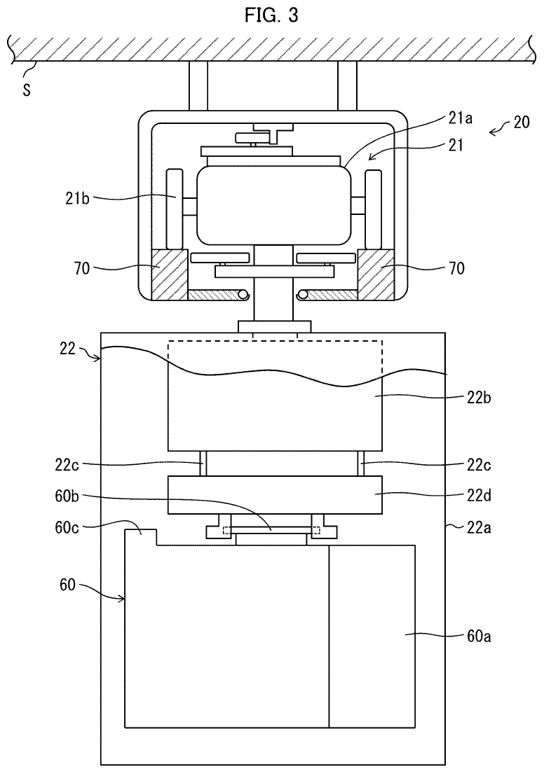

FIG. 1 is a front view illustrating a configuration of the conveyance system 100. FIG. 2 is a plan view illustrating an arrangement configuration of an inter-floor conveyance device 10, delivery conveyors 30, and intermediate conveyors 3 in the conveyance system 100. FIG. 3 is a front view illustrating a configuration of a ceiling conveyance device 20 in the conveyance system 100.

As illustrated in FIG. 1 and FIG. 2, the conveyance system 100 includes the inter-floor conveyance device 10, the ceiling conveyance devices 20 (intra-floor conveyance devices), delivery conveyors 30 (delivery conveyance devices), air blowers 40, and a storage shelf 50.

The inter-floor conveyance device 10 is a device configured to convey a container 60 (conveyance target) across the floors. The inter-floor conveyance device 10 will be described later in detail.

The following will describe the container 60. As illustrated in FIG. 3, the container 60 has a storage part 60a, a flange part 60b, and a protrusion 60c. In a case where the conveyance system 100 is provided in semiconductor manufacturing facility, the storage part 60a stores, for example, a semiconductor wafer. The flange part 60b is provided in a central portion on a top plate of the container 60. The protrusion 60c is formed, so as to protrude upward, at the entire rear end part on the top plate of the container 60 along a width direction (a direction orthogonal to a left-and-right direction and a vertical direction in FIG. 3) of the container 60.

The ceiling conveyance devices 20 are carriers configured to travel along tracks 70 hung from ceilings S on the floors (within the floors). FIG. 1 shows an example in which the ceiling conveyance devices 20 travel on a ceiling S1 on the first floor and on a ceiling S2 on the second floor. As illustrated in FIG. 3, each of the ceiling conveyance devices 20 has a traveling part 21 and a body part 22.

Rolling of a plurality of wheels 21b driven by a driving motor 21a on the track 70 causes the traveling part 21 to travel.

The body part 22 includes a frame 22a, a raising and lowering driving part 22b, a plurality of raising and lowering belts 22c, and a gripping part 22d. The frame 22a, which protects the container 60, is open at a lower part and side parts thereof for delivery of the container 60. The raising and lowering driving part 22b winds up or down the raising and lowering belts 22c by a rotation driving force generated by the motor thereof. The raising and lowering driving part 22b winds up the raising and lowering belts 22c to raise the gripping part 22d and winds down the raising and lowering belts 22c to lower the gripping part 22d. The gripping part 22d opens and closes a chuck thereof between a gripping position to grip the flange part 60b of the container 60 and a releasing position to release the gripping by the flange part 60b.

The delivery conveyors 30 are conveyance devices configured to convey the containers 60 between transfer mechanisms 5 described later or the intermediate conveyors 3 described later, and the ceiling conveyance devices 20. The delivery conveyors 30 deliver the containers 60 directly or via the intermediate conveyors 3 to and from the transfer mechanisms 5 and deliver the containers 60 to and from the ceiling conveyance devices 20. The detail of the delivery conveyors 30 will be described together with the detail of the inter-floor conveyance device 10.

The air blowers 40 are machines configured to blow air into a structure 1 (described later) provided to the inter-floor conveyance device 10. The air blowers 40 send out cleaned air in order to keep the air in the structure 1 clean. Therefore, as the air blowers 40, fan filter units are preferably used. The arrangement of the air blowers 40 will be described together with the detail of the inter-floor conveyance device 10.

The storage shelf 50 is a shelf configured to temporarily store the container 60. The arrangement of the storage shelf 50 will be described together with the detail of the inter-floor conveyance device 10. The detail of the storage shelf 50 will be described later.

### Configuration of Inter-Floor Conveyance Device

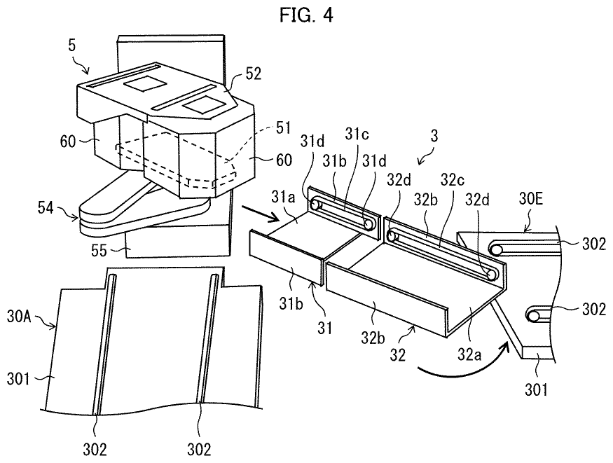

FIG. 4 is a perspective view illustrating an arrangement configuration of the transfer mechanism 5, the delivery conveyor 30, and the intermediate conveyor 3.

The inter-floor conveyance device 10 includes the structure 1, raising and lowering sections 2, and the intermediate conveyors 3 (intermediate conveyance sections).

The structure 1 forms a framework surrounding the raising and lowering sections 2 and part of each intermediate conveyor 3 and is provided so as to penetrate through the floors. The structure 1 has a lower stage 11 and an upper stage 12 on each floor. The lower stage 11 is disposed in a lower portion of each of the floors which corresponds to a predetermined vertical range, specifically, is disposed in a range of a height at which a person moves around. The upper stage 12 is disposed in an upper portion of each of the floors which corresponds to predetermined a vertical range, specifically, a range higher than the height at which a person moves around. As described later, only the lower stage 11 (11F) disposed on the floor surface F on the first floor has a structure different from those of the lower stages 11 on the second or upper floors.

Note that the floor surface on each floor above the second floor is provided above the ceiling S immediately below the floor, but is omitted in FIG. 1 for simplicity.

As illustrated in FIG. 2, an inner region IR1 surrounded by the lower stage 11F has a quadrangular shape. An inner region IR2 surrounded by the upper stage 12 has a quadrangular shape identical to that of the inner region IR1 as a whole, and some of the four corner regions are missing. In the example illustrated in FIG. 2, assuming that a side on which the raising and lowering mechanism 4 (described later) inside the structure 1 is disposed is a rear side, the two corner regions of the inner region IR2 on a front side of the quadrangular shape are missing. An inner region IR3 surrounded by the lower stage 11 disposed on each of the second or upper floors has a quadrangular shape that can be contained in the inner region IR2.

Each lower stage 11 includes a frame 11a forming the outer framework thereof and walls 11b fitted into the frame 11a. The lower stage 11 separates the inside from the outside thereof with the walls 11b over the entire outer periphery. The storage shelf 50 is disposed inside the lower stage 11F.

Each upper stage 12 includes a transfer part 121 and a non-transfer part 122. The non-transfer part 122 is provided on the transfer part 121.

The transfer part 121 is a portion where the container 60 is transferred between the transfer mechanisms 5 and the delivery conveyors 30. The transfer part 121 has a frame 121a forming the outer framework thereof. The container 60 is transferred through opening portions of the frame 121a. A wall is fitted to a portion on the above-described rear side of the frame 121a through which the container 60 is not transferred, although not illustrated.

The non-transfer part 122 has a frame 122a forming the outer framework thereof and a wall 122b fitted to the frame 122a. The non-transfer part 122 separates the inside from the outside thereof with the wall 122b over the entire outer periphery. The above-described air blowers 40 are each disposed on a wall surface of the wall 122b provided in such a certain vertical range.

On the upper end surface of the non-transfer part 122 on each floor, the wall 122b covers a part around the lower stage 11 on the upper floor, although not illustrated. Further, on the lower end surface of the transfer part 121 on each of the second or upper floors, the wall 122b covers a part around the lower stage 11 on the same floor, although not illustrated.

The plurality of delivery conveyors 30 are disposed around the transfer part 121. In the example illustrated in FIG. 2, delivery conveyors 30A to 30E are disposed as the delivery conveyors 30.

The delivery conveyor 30A is disposed in front of each of the transfer mechanisms 5. The delivery conveyor 30B is disposed on one lateral side of the transfer mechanism 5, and the delivery conveyor 30C is disposed on the other lateral side of the transfer mechanism 5. The delivery conveyor 30D is disposed on a lateral side of the delivery conveyor 30A closer to the delivery conveyor 30B so as to be parallel to the delivery conveyor 30A. The delivery conveyor 30E is disposed on a lateral side of the delivery conveyor 30C closer to the delivery conveyor 30A so as to be parallel to the delivery conveyor 30C.

Each of the delivery conveyors 30A to 30C is disposed so that an end part thereof is positioned in the vicinity of the transfer mechanism 5 and directly transfers the container 60 to and from the transfer mechanism 5. Each of the delivery conveyors 30D and 30E is disposed so that an end part thereof is positioned apart from the transfer mechanism 5 and transfers the container 60 to and from the transfer mechanism 5 via the intermediate conveyor 3.

Each of the delivery conveyors 30 is made up from, for example, a double belt conveyor and includes a conveyance base 301 and a pair of conveyance belts 302. The conveyance base 301 is a plate-shaped platform formed so as to be long in a conveyance direction. The conveyance belts 302, which are endless belts disposed in the left and right of the conveyance direction and having a relatively narrow width, are driven by the motor via a driving roller.

Each of the intermediate conveyors 3 conveys the container 60 between the transfer mechanism 5 and the delivery conveyor 30D or 30E. The intermediate conveyor 3 is configured to, inside the structure 1, deliver the container 60 to and from the transfer mechanism 5 and to, outside the structure 1, deliver the container 60 to and from the delivery conveyor 30. The intermediate conveyor 3 is disposed across the inside of the structure 1 and the outside of the structure 1.

In the example of FIG. 2, a conveyance path of the intermediate conveyors 3 is located on a line connecting the transfer mechanism 5 and the delivery conveyor 30D. The other conveyance path of the intermediate conveyors 3 is located on a line connecting the transfer mechanism 5 and the delivery conveyor 30E. The conveyance paths of the intermediate conveyors 3 are at least partially disposed in respective triangular missing regions L (areas indicated in gray in FIG. 2) corresponding to the above-described corner regions which are missing.

As illustrated in FIG. 4, each of the intermediate conveyors 3 includes a first conveyance part 31 and a second conveyance part 32 (turning part). As in the case of the delivery conveyors 30, the first conveyance part 31 and the second conveyance part 32 are each made up from a double belt conveyor. The first conveyance part 31 is disposed in the vicinity of the transfer mechanism 5 and conveys the container 60 between the transfer mechanism 5 and the second conveyance part 32. The second conveyance part 32 is disposed in the vicinity of a delivery conveyor 30 and conveys the container 60 between the first conveyance part 31 and the delivery conveyor 30 to deliver the container 60 to and from the delivery conveyor 30.

The first conveyance part 31 includes a bottom plate part 31a, a pair of side parts 31b, a pair of conveyance belts 31c, and two pairs of driving rollers 31d. The side parts 31b are plate-shaped portions provided so as to stand on both side edges of the bottom plate part 31a formed into a quadrangular shape. The respective conveyance belts 31c are provided on the facing surfaces of the pair of side parts 31b. The conveyance belts 31c, which are endless belts having a relatively narrow width, are each driven by a driving motor via the pair of two driving rollers 31d.

The second conveyance part 32 has a bottom plate part 32a, a pair of side parts 32b, and a pair of conveyance belts 32c, and two pairs of driving rollers 32d. The side parts 32b are plate-shaped portions provided so as to stand on both side edges of the bottom plate part 32a formed into a quadrangular shape. The respective conveyance belts 32c are provided on the facing surfaces of the pair of side parts 32b. The conveyance belts 32c, which are endless belts having a relatively narrow width, are each driven by a driving motor via the pair of two driving rollers 32d.

Each of the transfer mechanisms 5 can hold two containers 60 at the same time as described later. In connection with this configuration, each of the intermediate conveyors 3 can deliver the two containers 60 to and from the transfer mechanism 5 at the same time. Specifically, the first conveyance part 31 and the second conveyance part 32 each allow one container 60 to be placed thereon.

When the first conveyance part 31 and the second conveyance part 32 each deliver the container 60 to and from the transfer mechanism 5 and when the first conveyance part 31 and the second conveyance part 32 deliver the container 60 to and from each other, the conveyance directions of the first conveyance parts 31 and the second conveyance part 32 agree with the conveyance path, as illustrated in FIG. 2. When the second conveyance part 32 delivers the container 60 to and from the delivery conveyor 30D or 30E, the second conveyance part 32 turns in the direction of the arrow in a horizontal plane so as to match the conveyance direction thereof and the conveyance direction of the delivery conveyor 30D or 30E.

Note that the arrangement example of the intermediate conveyors 3 and the delivery conveyors 30 is not limited to the example illustrated in FIG. 2.

### Configuration of Raising and Lowering Section

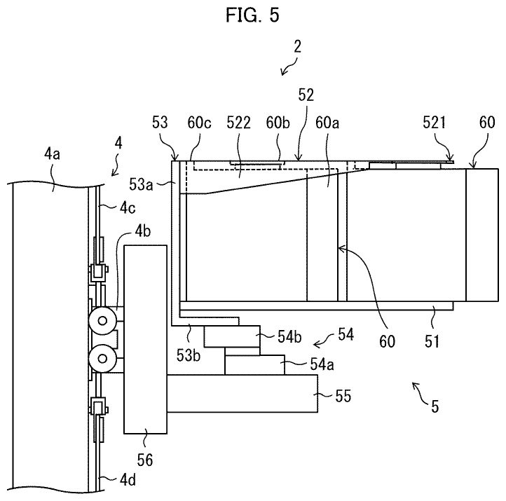

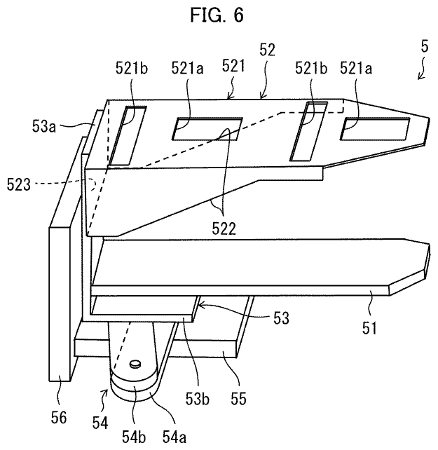

FIG. 5 is a side view illustrating the configuration of a raising and lowering section 2 included in the inter-floor conveyance device 10. FIG. 6 is a perspective view illustrating the transfer mechanism 5.

Each of the raising and lowering sections 2 includes a raising and lowering mechanism 4 and the transfer mechanism 5.

As illustrated in FIG. 5, the raising and lowering mechanism 4 includes a guide rail 4a, a raising and lowering platform 4b, a first raising and lowering belt 4c, and a second raising and lowering belt 4d in order to move the transfer mechanism 5 in a vertical direction.

The guide rail 4a, which has a tubular shape, is disposed so as to penetrate through the floors in a range in which the transfer mechanism 5 moves vertically. Inside the guide rail 4a, a balance weight (not shown) is disposed so as to be movable in a vertical direction. The raising and lowering platform 4b has s wheels configured to roll so that a wall surface of the guide rail 4a is sandwiched between the wheels from the inside and the outside of the guide rail 4a.

The first raising and lowering belt 4c has one end connected to an upper end of the raising and lowering platform 4b and the other end connected to an upper end of the balance weight. The second raising and lowering belt 4d has one end connected to a lower end of the raising and lowering platform 4b and the other end connected to a lower end of the balance weight. In the linked mechanism in which the raising and lowering platform 4b, the first raising and lowering belt 4c, the second raising and lowering belt 4d, and the balance weight are connected, the first raising and lowering belt 4c is moved in a vertical direction by a rotation driving device (not illustrated) provided at an upper end of the guide rail 4a to raise and lower the raising and lowering platform 4b.

The transfer mechanism 5 moves with use of the raising and lowering mechanism 4 in a vertical direction across the plurality of floors while holding the container 60, and transfers the container 60. As illustrated in FIG. 6, each of the transfer mechanisms 5 includes a raising and lowering plate 51, a holding plate 52, a movement support part 53, a bendable link 54, a support platform 55, and a raising and lowering support 56.

The raising and lowering plate 51 is a plate member having a length that allows the two containers 60 to be placed thereon. For positioning the container 60, a plurality of protrusions to be fitted with recesses provided on the bottom surface of the container 60 are provided on the upper surface of the raising and lowering plate 51, although not illustrated. The raising and lowering plate 51 is driven to be raised and lowered by the movement support part 53.

The holding plate 52, which is a member that presses and holds the upper end surface of the container 60 placed on the raising and lowering plate 51, is disposed above the raising and lowering plate 51 so as to be parallel to the raising and lowering plate 51. The holding plate 52 includes a top plate part 521, a pair of side plate parts 522, and a support plate part 523. The top plate part 521, which is a portion to be brought into contact with the upper end surface of the container 60, has a length that can press the two containers 60.

The top plate part 521 is provided with two first openings 521a and two second openings 521b, the first openings 521a and the second openings 521b being spaced from each other in a longitudinal direction of the top plate part 521. Each of the first openings 521a has a shape and size substantially identical to those of the flange part 60b of the container 60. Into the first opening 521a, the flange part 60b is fitted. Each of the second openings 521b has a shape and size substantially identical to those of the protrusion 60c of the container 60. Into the second opening 521b, the protrusion 60c is fitted.

The support plate part 523 is provided on a rear end side that is opposite to a front end side of the top plate part 521 which is a side on which the holding plate 52 receives the container 60. The support plate part 523 is formed so as to hang down from the rear end edge of the top plate part 521. The support plate part 523 is fixed to an upper part of a raising and lowering support plate 53a (described later) of the movement support part 53.

The side plate parts 522 are formed so as to hang down from both side ends of the top plate part 521. The side plate parts 522 are provided to prevent the container 60 from protruding due to the turning of the raising and lowering plate 51 and the holding plate 52.

The movement support part 53 moves with use of the bendable link 54. The movement support part 53 supports the raising and lowering plate 51 so as to allow the raising and lowering plate 51 to be raised and lowered and fixes the top plate part 521. The movement support part 53 includes a raising and lowering support plate 53a and a movement support plate 53b.

The raising and lowering support plate 53a is formed so as to extend in a vertical direction and contains a raising and lowering driving mechanism which is not illustrated. When the container 60 is delivered to and from the intermediate conveyor 3, the raising and lowering support plate 53a lowers the raising and lowering plate 51 to the lowermost position of the movable range with use of the raising and lowering driving mechanism. On raising and lowering of the transfer mechanism 5, the raising and lowering support plate 53a raises the raising and lowering plate 51 to the uppermost position of the movable range with use of the raising and lowering driving mechanism. The movement support plate 53b is formed so as to extend from the lower end of the raising and lowering support plate 53a in a direction perpendicular to the raising and lowering support plate 53a. The movement support plate 53b is driven by the bendable link 54.

The bendable link 54 moves the movement support part 53 between a raising and lowering position and a delivery position through bending and straightening of two arms 54a and 54b thereof. The raising and lowering position is a position assumed when the transfer mechanism 5 is raised and lowered, as illustrated in FIG. 6. The delivery position is a position assumed when the container 60 is delivered between the end part of each of the delivery conveyors 30A to 30C and the first conveyance part 31 of the intermediate conveyor 3.

The support platform 55 is a platform supporting the bendable link 54. The support platform 55 contains a driving mechanism configured to drive the bendable link 54.

The raising and lowering support 56, which supports the support platform 55, is fixed to the raising and lowering platform 4b of the raising and lowering mechanism 4. The raising and lowering support 56 thus raises and lowers the transfer mechanism 5 along the guide rail 4a.

### Configuration of Storage Shelf

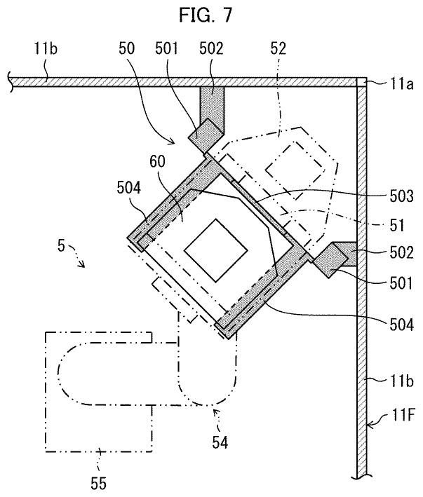

FIG. 7 is a plan view illustrating a configuration of the storage shelf 50 provided in the lowermost part of the inter-floor conveyance device 10.

As illustrated in FIG. 7, the storage shelf 50 includes two support pillars 501, four fixing parts 502, an intermediate support plate 503, and two support parts 504.

The support pillars 501 are provided, so as to stand on the floor surface F, near the frame 11a disposed at a corner part of the lower stage 11F. One support pillar 501 is disposed in the vicinity of a wall 11b disposed on one side of the frame 11a in a horizontal direction. The other support pillar 501 is disposed in the vicinity of a wall 11b disposed on the other side of the frame 11a in a horizontal direction.

The fixing parts 502 fix the support pillars 501 to the walls 11b so as to connect the upper ends and the lower ends of the support pillars 501 and the walls 11b.

The intermediate support plate 503 is provided so as to connect intermediate parts of the two support pillars 501. As illustrated also in FIG. 1, the intermediate support plate 503 has a recess in an upper part of an intermediate portion thereof so as to allow the raising and lowering plate 51 of the transfer mechanism 5 to pass therethrough.

The support parts 504 are plate-shaped portions provided so as to extend parallel to each other from both end parts at an upper end edge of the intermediate support plate 503 in a direction perpendicular to a surface of the intermediate support plate 503. The support parts 504 each have a length that can support one container 60.

The storage shelf 50 configured as described above supports and stores only one container 60 that the transfer mechanism 5 holds in a holding position on a deeper side thereof. FIG. 7 shows a configuration in which the storage shelf 50 is provided near one corner part of the four corner parts of the lower stage 11F. However, storage shelves 50 may be provided at two corner parts in a movable range of the transfer mechanism 5.

### Operation of Inter-Floor Conveyance Device

For example, as illustrated in FIG. 4, the bendable link 54 of the transfer mechanism 5 turns the raising and lowering plate 51 and the holding plate 52 so as to direct the container 60 toward the direction of the arrow. At the same time as the turning, the bendable link 54 causes the raising and lowering plate 51 and the holding plate 52 to travel straight in the direction of the arrow until the two containers 60 reach an area above the intermediate conveyor 3. The transfer mechanism 5 lowers the raising and lowering plate 51 in a position in which the two containers 60 reach an area above the intermediate conveyor 3. Thus, the container 60 held on the deeper side of the raising and lowering plate 51 and the holding plate 52 is placed on the conveyance belts 31c of the first conveyance part 31, and the container 60 held on a front side of the raising and lowering plate 51 and the holding plate 52 is placed on the conveyance belts 32c of the second conveyance part 32.

The second conveyance part 32 turns in the direction of the arrow from the direction illustrated in FIG. 4 so as to match the conveyance direction thereof and the conveyance direction of the delivery conveyor 30E. The second conveyance part 32 then drives the conveyance belts 32c to convey the container 60 placed on the conveyance belts 32c to the delivery conveyor 30E. In this way, the container 60 is delivered from the second conveyance part 32 to the delivery conveyor 30.

After the delivery of the container 60 from the second conveyance part 32 to the delivery conveyor 30 has been completed, the second conveyance part 32 turns to the position illustrated in FIG. 4. In this state, the first conveyance part 31 drives the conveyance belts 31c to convey the container 60 placed on the conveyance belts 31c to the second conveyance part 32. The second conveyance part 32 conveys the container 60 that has been conveyed from the first conveyance part 31, to deliver the container 60 to the delivery conveyor 30 as described above.

In a case where the two containers 60 that have been conveyed by the delivery conveyor 30E are conveyed to the transfer mechanism 5, the container 60 is delivered from the delivery conveyor 30 to the second conveyance part 32 facing in a direction such that the conveyance direction of the second conveyance part 32 agrees with that of the delivery conveyor 30. The second conveyance part 32 then turns to the position illustrated in FIG. 4 to convey the container 60 to the first conveyance part 31. Subsequently, the second conveyance part 32 turns in the direction of the arrow and reaches a direction that agrees with the conveyance direction of the delivery conveyor 30. The container 60 is then delivered from the delivery conveyor 30 to the second conveyance part 32. Afterwards, the second conveyance part 32 turns to return to the position illustrated in FIG. 4.

From this state, the bendable link 54 causes the raising and lowering plate 51 and the holding plate 52 to advance to the intermediate conveyor 3. After the raising and lowering plate 51 and the holding plate 52 hold the two containers 60 placed on the first conveyance part 31 and the second conveyance part 32, the bendable link 54 moves the raising and lowering plate 51 and the holding plate 52 to the raising and lowering position described above. The raising and lowering mechanism 4 raises and lowers the transfer mechanism 5 in this state.

Also in a case where the container 60 is conveyed between the transfer mechanism 5 and the delivery conveyor 30D, the transfer mechanism 5 and the intermediate conveyor 3 operate in the same manner as described above.

In a case where the containers 60 are delivered from the transfer mechanism 5 to the delivery conveyor 30A, the bendable link 54 turns the raising and lowering plate 51 and the holding plate 52 so as to direct the containers 60 toward the conveyance direction of the delivery conveyor 30A. From this state, the bendable link 54 causes the raising and lowering plate 51 and the holding plate 52 to travel straight in a conveyance direction of the delivery conveyor 30A until the two containers 60 reach an area above the delivery conveyor 30A. The transfer mechanism 5 lowers the raising and lowering plate 51 in a position in which the two containers 60 reach an area above the delivery conveyor 30A. Thus, the two containers 60 held by the raising and lowering plate 51 and the holding plate 52 are placed on the delivery conveyor 30A.

In a case where the transfer mechanism 5 receives the two containers 60 that have been conveyed by the delivery conveyor 30A, the bendable link 54 moves the raising and lowering plate 51 and the holding plate 52 to a position that allows them to hold the two containers 60. After the raising and lowering plate 51 and the holding plate 52 hold the two containers 60 placed on the delivery conveyor 30A, the bendable link 54 moves the raising and lowering plate 51 and the holding plate 52 to a raising and lowering position. The raising and lowering mechanism 4 raises and lowers the transfer mechanism 5 in this state.

Also in a case where the container 60 is conveyed between the transfer mechanism 5 and the delivery conveyor 30B or 30C, the transfer mechanism 5 and the intermediate conveyor 3 operate in the same manner as the case where the container 60 is conveyed between the transfer mechanism 5 and the delivery conveyor 30A.

### Effects of Embodiment

The inter-floor conveyance device 10 in accordance with the present embodiment includes the intermediate conveyors 3, thereby allowing the inter-floor conveyance device 10 to convey the container 60 between each of the intermediate conveyors 3 and each of the delivery conveyors 30D and 30E. Thus, the distance between the transfer mechanism 5 and each of the delivery conveyors 30D and 30E can be widened so as to secure the conveyance paths of the intermediate conveyors 3. Therefore, in the configuration illustrated in FIG. 2, it is possible that a delivery conveyor 30 facing in the same direction as the delivery conveyor 30E is disposed between the delivery conveyors 30B and 30D, and a delivery conveyor 30 facing in the same direction as the delivery conveyor 30A is disposed between the delivery conveyors 30A and 30E. This enables more delivery conveyors 30 to be disposed around the transfer mechanisms 5.

The first conveyance part 31 of each intermediate conveyor 3 is disposed inside the transfer part 121 of the structure 1 and delivers the container 60 to and from each transfer mechanism 5 inside the transfer part 121. The second conveyance part 32 of each intermediate conveyor 3 is disposed outside the transfer part 121 of the structure 1, specifically, in a missing region L and delivers the container 60 to and from each delivery conveyor 30 outside the transfer part 121.

In a conventional inter-floor conveyance device, the container 60 is delivered to and from the delivery conveyor 30 inside the structure. Therefore, it is necessary to secure a wide area of the structure on each floor. In contrast, with the above-described configuration, the second conveyance part 32 delivers the container 60 to and from the delivery conveyor 30 outside the transfer part 121. This enables the area of the structure 1 (transfer part 121) on each floor to be reduced. This makes it possible to reduce the materials of the structure 1, particularly the materials of the frame 121a making up the transfer part 121 and the materials of the wall 122b making up the non-transfer part 122 and to save the time and effort for the work to install the structure 1.

Since the transfer part 121 is formed so as to have the missing regions L, the structure 1 has a somewhat complicated structure. However, since only parts on missing region L sides become complicated, the complexity of the structure 1 can be minimized.

The transfer part 121 is disposed at a position higher than a height at which a person moves around on each floor. Therefore, even when the second conveyance part 32 disposed outside the structure 1 turns, there is no risk that the second conveyance part 32 collides with a person.

The second conveyance part 32 turns in a horizontal plane. This enables the container 60 to be delivered between the second conveyance part 32 and each of the delivery conveyor 30D and 30E disposed in different directions. Further, the turning of the second conveyance part 32 in a horizontal plane including the missing regions L enables the second conveyance part 32 to turn in the vicinity of the structure 1. This enables the conveyance paths of the intermediate conveyors 3 to be shortened, thereby making it possible to avoid an increase in size of the intermediate conveyors 3.

The structure 1 includes the lower stage 11 having the inner regions IR1 and IR3 each having a quadrangular shape. Thus, there is no need to make a missing corner region except in an area in which the container 60 is delivered to each delivery conveyor 30. Therefore, there is no need to use a special structural member for configuring the structure 1 so as to make a missing corner region. This makes it possible to construct the structure 1 with use of standard members as structural members.

Each air blower 40 is disposed on the wall 122b of the non-transfer part 122 of the structure 1. The air blower 40 that provides a large air volume can be attached on each floor to the wall surface capable of securing such a large area. This makes it possible to secure a sufficient air volume toward the inside of the structure 1.

It has been conventionally performed to temporarily store the container 60 utilizing a surplus space inside the structure 1. Unfortunately, reducing the area of the transfer part 121 as described above makes it impossible to secure the surplus space described above inside the transfer part 121. However, disposing the storage shelf 50 inside the lower stage 11F makes it possible to secure a temporary storage space for the container 60.

Aspects of the present invention can also be expressed as follows:

As described above, an inter-floor conveyance device in accordance with Aspect 1 of the present invention includes: a raising and lowering section including a transfer mechanism configured to move in a vertical direction across a plurality of floors while holding a conveyance target and configured to transfer the conveyance target; and an intermediate conveyance section configured to deliver the conveyance target between the transfer mechanism and each of delivery conveyance devices configured to deliver the conveyance target to and from an intra-floor conveyance device configured to convey the conveyance target.

In the above-described configuration, the intermediate conveyance section conveys the conveyance target between the transfer mechanism and each of the delivery conveyance devices. Thus, the distance between the transfer mechanism and the delivery conveyance device can be widened so as to secure the conveyance path of the intermediate conveyance section. This makes it possible to dispose more delivery conveyance devices around the transfer mechanism.

An inter-floor conveyance device in accordance with Aspect 2 of the present invention is configured, in Aspect 1 above, to further include a structure surrounding the raising and lowering section and part of the intermediate conveyance section, the intermediate conveyance section being disposed across an inside of the structure and an outside of the structure, the intermediate conveyance section being configured to, inside the structure, deliver the conveyance target to and from the transfer mechanism and to, outside the structure, deliver the conveyance target to and from each of the delivery conveyance devices.

In the above-described configuration, the intermediate conveyance section delivers the conveyance target to and from each of the delivery conveyance devices outside the structure. This makes it possible to reduce an area of the structure on each floor, compared to a configuration in which the conveyance target is delivered to and from the delivery conveyance device inside the structure. Therefore, it is possible to reduce the size of the structure.

An inter-floor conveyance device in accordance with Aspect 3 of the present invention is configured, in Aspect 2 above, such that: an inner region in a horizontal plane has a quadrangular shape as a whole in a predetermined vertical range, the inner region being surrounded by the structure; at least one of four corner regions of the quadrangular shape is missing in the predetermined vertical range; and a conveyance path of the intermediate conveyance section is at least partially disposed in a missing region corresponding to the at least one corner region which is missing.

In the above-described configuration, the structure has a somewhat complicated structure in order to cause the structure to have the missing corner region. However, the intermediate conveyance section makes it possible to deliver the conveyance target to and from each of the delivery conveyance devices outside the structure while the complexity of the structure is minimized.

An inter-floor conveyance device in accordance with Aspect 4 of the present invention is configured, in Aspect 3 above, such that the intermediate conveyance section includes, in the missing region, a turning part configured to turn in a horizontal plane and configured to deliver the conveyance target to and from each of the delivery conveyance devices.

In the above-described configuration, the turning of the turning part of the intermediate conveyance section enables the intermediate conveyance section to deliver the conveyance target to and from each of the delivery conveyance devices disposed in different directions. Further, the turning part can turn in the vicinity of the structure by turning in a horizontal plane including the corner regions. This enables the conveyance path of the intermediate conveyance section to be shortened, thereby making it possible to avoid increase in size of the intermediate conveyance section.

An inter-floor conveyance device in accordance with Aspect 5 of the present invention is configured, in Aspect 3 or 4 above, such that the inner region has a quadrangular shape in at least part of a vertical range, the at least part being different from the predetermined vertical range.

The above-described configuration makes it unnecessary to make a missing corner region except in an area in which the conveyance target is delivered to each of the delivery conveyance devices. This enables the structure to be constructed with use of standard members as structural members, without special structural members to construct the structure so as to make a missing corner region.

An inter-floor conveyance device in accordance with Aspect 6 of the present invention is configured, in Aspect 5 above, to further include an air blower configured to blow air into the structure, the air blower being disposed on a wall surface provided in a certain vertical range in which the inner region has a quadrangular shape.

The above-described configuration makes it possible to attach the air blower on a wall surface of the structure which can secure a large area. Thus, it is possible to secure a sufficient air volume toward the inside of the structure.

### Additional Remarks

The present invention is not limited to the embodiments above, but can be altered in various ways by a skilled person in the art within the scope of the claims. The present invention also encompasses, in its technical scope, any embodiment derived by combining technical means disclosed in differing embodiments.

### REFERENCE SIGNS LIST

1 Structure
2 Raising and lowering section
3 Intermediate conveyor (intermediate conveyance section)
10 Inter-floor conveyance device
20 Ceiling conveyance device (intra-floor conveyance device)
30 Delivery conveyor (delivery conveyance device)
32 Second conveyance part (turning part)
60 Container (conveyance target)
IR1 to IR3 Inner region
L Missing region

1. An inter-floor conveyance device comprising:
a raising and lowering section including a transfer mechanism configured to move in a vertical direction across a plurality of floors while holding a conveyance target and configured to transfer the conveyance target; and
an intermediate conveyance section configured to deliver the conveyance target between the transfer mechanism and each of delivery conveyance devices configured to deliver the conveyance target to and from an intra-floor conveyance device configured to convey the conveyance target.

2. The inter-floor conveyance device according to claim 1, further comprising a structure surrounding the raising and lowering section and part of the intermediate conveyance section,
the intermediate conveyance section being disposed across an inside of the structure and an outside of the structure,
the intermediate conveyance section being configured to, inside the structure, deliver the conveyance target to and from the transfer mechanism and to, outside the structure, deliver the conveyance target to and from each of the delivery conveyance devices.

3. The inter-floor conveyance device according to claim 2, wherein:
an inner region in a horizontal plane has a quadrangular shape as a whole in a predetermined vertical range, the inner region being surrounded by the structure;
at least one of four corner regions of the quadrangular shape is missing in the predetermined vertical range; and a conveyance path of the intermediate conveyance section is at least partially disposed in a missing region corresponding to the at least one corner region which is missing.

4. The inter-floor conveyance device according to claim 3, wherein the intermediate conveyance section includes, in the missing region, a turning part configured to turn in a horizontal plane and configured to deliver the conveyance target to and from each of the delivery conveyance devices.

5. The inter-floor conveyance device according to claim 3, wherein the inner region has a quadrangular shape in at least part of a vertical range, the at least part being different from the predetermined vertical range.

6. The inter-floor conveyance device according to claim 5, further comprising an air blower configured to blow air into the structure,
the air blower being disposed on a wall surface provided in a certain vertical range in which the inner region has a quadrangular shape.
